(19) United States
(12) Patent Application Publication
(10) Pub. No.: US 2026/0287661 A1
(43) Pub. Date: Sep. 24, 2026

(54) BATTERY SENSING DEVICE

(71) Applicant: Renesas Design (UK) Limited, Bourne End (GB)

(72) Inventors: Paolo BARUZZI, Portland, OR (US); Alisdair MUIR, Edinburgh (GB); Anthony GRIBBEN, Edinburgh (GB); Thomas MAYERWIESER, Dalkeith (GB)

(73) Assignee: Renesas Design (UK) Limited, Bourne End (GB)

(21) Appl. No.: 19/082,737

(22) Filed: Mar. 18, 2025

(51) Int. Cl. G01R 31/3842; G01R 1/20; G01R 19/25; G01R 31/364; G01R 31/367; G01R 31/392

(52) U.S. Cl. CPC G01R 31/3842; G01R 1/203; G01R 19/2509; G01R 31/364; G01R 31/392; G01R 31/367

(57) ABSTRACT

A battery sensing device for sensing an output voltage and/or an output current of a battery is provided. The battery sensing device includes one or more filter circuits, and an analog to digital converter (ADC). At least one of the one or more filter circuits and/or the ADC is adjustable.

The present disclosure relates to a battery sensing device for sensing an output voltage and/or an output current of a battery.

### BACKGROUND

For portable electronic systems, accurate monitoring of battery output voltage and battery output current are very important to provide critical system level functions. For example, accurate fuel gauge and battery health and management functions rely on accurate sensing of real time output characteristics.

Portable devices may reduce power consumption by turning on and turning off power hungry functions such as display illumination and computationally intensive CPU functions, as required. The enabling/disabling functionality causes the output current of a battery to have dynamic AC characteristics. Depending on the types of applications that are being performed, the frequency of the AC characteristics can range from 0 Hz (DC operation) to 50 Hz, and as high as 500 Hz. The output current range may dynamically transition from approximately 100 mA to greater than 1 A. The dynamic nature of the battery can add to the complexity of battery output voltage and output current sensing.

### SUMMARY

It is desirable to provide an improved battery sensing device for sensing an output voltage and/or output current of a battery.

According to a first aspect of the disclosure there is provided a battery sensing device for sensing an output voltage and/or an output current of a battery, the battery sensing device comprising one or more filter circuits, and an analog to digital converter (ADC), wherein at least one of the one or more filter circuits and/or the ADC is adjustable.

Optionally, the sampling frequency of the ADC is greater than or equal to 20 kHz.

Optionally, the one or more filter circuits comprises an analog filter circuit, and a digital filter circuit, and at least one of the analog filter circuit, the digital filter circuit and/or the ADC is adjustable.

For example, the ADC may be adjustable by adjustment of its sampling frequency.

Optionally, the analog filter circuit is configured to receive a parameter signal from the battery, the parameter signal being dependent on the output voltage or the output current, filter the parameter signal, the ADC is configured to receive the parameter signal after filtering by the analog filter circuit, convert the parameter signal, as received by the ADC, to a digital parameter signal, and the digital filter circuit is configured to receive the digital parameter signal, and filter the digital parameter signal.

Optionally, the parameter signal is dependent on the output voltage, and the battery sensing device comprises a multiplexer circuit, the parameter signal being provided to the ADC, after filtering by the analog filter circuit, via the multiplexer circuit.

Optionally, the battery sensing device comprises an over/under protection circuit.

Optionally, the battery sensing device comprises a first input terminal and a second input terminal configured to be couplable to battery terminals of the battery for sensing the parameter signal when the parameter signal is dependent on the output voltage, or sense resistor terminals of a sense resistor coupled to the battery for sensing the parameter signal when the parameter signal is dependent on the output current.

Optionally, the analog filter circuit comprises a passive anti-aliasing filter or an active anti-aliasing filter.

Optionally, the passive anti-aliasing filter comprises a first capacitor, a first resistive element coupled to a first terminal of the first capacitor, a second resistive element coupled to a second terminal of the first capacitor.

Optionally, the battery sensing device comprises external capacitor terminals configured to permit parallel coupling of the first capacitor with a first external capacitor.

Optionally, the ADC comprises a delta sigma modulator.

Optionally, the active anti-aliasing filter is a first order or a second order filter.

Optionally, the active anti-aliasing filter comprises a differential amplifier configured to provide the filtered parameter signal to the ADC.

Optionally, the active anti-aliasing filter comprises a plurality of variable capacitors configured to enable adjustment of the analog filter circuit.

Optionally, the digital filter circuit comprises a plurality of digital filters arranged in a parallel configuration or arranged in a cascaded configuration.

Optionally, each of the plurality of digital filters is configured to downsample the parameter signal.

Optionally, each of the plurality of digital filters is configured to downsample the parameter signal at a rate that matches the filter order of the digital circuit. For example, each of the plurality of digital filters may down sample at a rate consistent with the filtering achieved by the digital circuit.

Optionally, the battery sensing device comprises a monitoring module configured to receive the digital parameter signal after filtering, and monitor the battery using the digital parameter signal, as received.

Optionally, the monitoring module or a system using the battery is configured to adjust the at least one of the analog filter circuit, the digital filter circuit and/or the ADC.

Optionally, the monitoring module or the system using the battery is configured to adjust the at least one of the analog filter circuit, the digital filter circuit and/or the ADC based on one or more of software execution on the system, detection of usage patterns, noise, detection of high frequency signals, and/or detecting a requirement for reduced current consumption.

Optionally, the monitoring module comprises a state of health unit, and/or a state of charge unit, and/or a Coulomb counter.

Optionally, the monitoring module comprises a unit filtering data for state of health, and/or a unit filtering data for a state of charge unit, and/or a unit filtering data for a Coulomb counter.

Optionally, the monitoring module comprises an output tailored for state of health, and/or an output tailored for state of charge, and/or an output tailored for Coulomb Counting.

Optionally, the battery sensing device is implemented on a circuit board or a chip.

Optionally, the ADC is 1 bit 2nd order delta sigma running at a sampling frequency.

Optionally, the ADC is 2nd order delta sigma with a multibit quantizer running at a scaled sampling frequency.

According to a second aspect of the disclosure there is provided a battery sensing system comprising a first battery sensing device for sensing an output voltage of a battery, the battery sensing device comprising one or more first filter circuits, and a first analog to digital converter (ADC), and a second battery sensing device for sensing an output current of the battery, the battery sensing device comprising one or more second filter circuits, and a second ADC, wherein at least one of the one or more first filter circuits and/or the first ADC and/or the one or more second filter circuits and/or the second ADC is adjustable.

It will be appreciated that the battery sensing system of the second aspect may include features set out in relation to the first aspect and may include other features as described herein. For example, one or both of the first battery sensing device and the second battery sensing device of the second aspect may include features set out in relation to the battery sensing device of the first aspect.

According to a third aspect of the disclosure there is provided a method of providing a battery sensing device for sensing an output voltage and/or an output current of a battery, the method comprising providing one or more filter circuits, and providing an analog to digital converter (ADC), wherein at least one of the one or more filter circuits and/or the ADC is adjustable.

It will be appreciated that the method of the third aspect may including using and/or providing features set out in relation the first and/or second aspects and may include other features as described herein.

### BRIEF DESCRIPTION OF THE DRAWINGS

The disclosure is described in further detail below by way of example and with reference to the accompanying drawings, in which:

FIG. 1 is a schematic of a known battery sensing device using an external analog filter;

FIG. 2A is a graph of the battery supplied current magnitude versus frequency for a practical implementation of the battery sensing device of FIG. 1, FIG. 2B shows the graph of FIG. 2A with additional labelling to highlight specific features, FIG. 2C is a graph showing how the DFT of the battery supplied current signal, as shown in FIG. 2B, changes when a system load is activated at specific frequencies;

FIG. 3A is a schematic of a battery sensing device for sensing an output voltage and/or an output current of a battery in accordance with a first embodiment of the present disclosure, FIG. 3B is a schematic of a specific implementation of the battery sensing device of FIG. 3A, in accordance with a second embodiment of the present disclosure, FIG. 3C is a schematic of a specific implementation of the battery sensing device in accordance with a third embodiment of the present disclosure;

FIG. 4 is a schematic of a specific implementation of the battery sensing device in accordance with a fourth embodiment of the disclosure;

FIG. 5A is a schematic of a portion of a specific implementation of the battery sensing device for sensing the output current of the battery, in accordance with a fifth embodiment of the present disclosure, FIG. 5B is a schematic of a portion of a specific implementation of the battery sensing device for sensing the output voltage of the battery, in accordance with a sixth embodiment of the present disclosure, FIG. 5C is a schematic of a portion of a battery sensing system comprising a portion of a battery sensing device for sensing the output current of the battery and a portion of a battery sensing device for sensing the output voltage of the battery, in accordance with a seventh embodiment of the present disclosure, FIG. 5D is a schematic of a portion of a specific implementation of the battery sensing device for sensing the output current of the battery, in accordance with an eighth embodiment of the present disclosure; and

FIG. 6A is a schematic of a battery sensing system comprising specific implementations of the battery sensing devices in accordance with a ninth embodiment of the present disclosure, FIG. 6B is a graph of the output current magnitude versus frequency for a practical implementation of one of the battery sensing devices of FIG. 6A, FIG. 6C is a schematic of a battery sensing system comprising specific implementations of the battery sensing devices, in accordance with a tenth embodiment of the disclosure, FIG. 6D is a graph of the output current magnitude versus frequency for a practical implementation of one of the battery sensing device of FIG. 6C, FIG. 6E is a schematic of a specific implementation of the battery sensing device with a specific implementation of the digital filter circuit of FIG. 6C.

### DETAILED DESCRIPTION

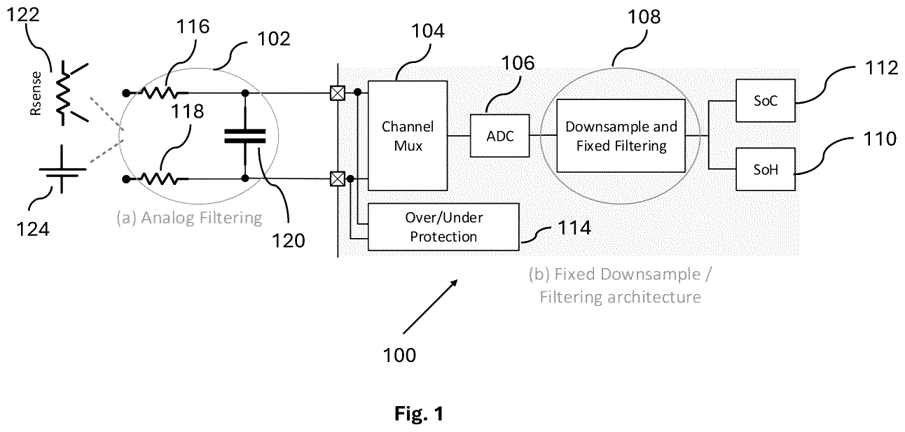

FIG. 1 is a schematic of a known battery sensing device 100 using an external analog filter 102. The battery sensing device 100 comprises a multiplexer 104, an analog to digital converter (ADC) 106, a digital filter 108, a state of health circuit 110, a state of charge circuit 112, and an over/under protection circuit 114.

The external analog filter 102 comprises resistors 116, 118 and a capacitor 120. During operation, the external analog filter 102 may be coupled to a sense resistor 122 that may be coupled in series with a battery 124, for sensing the output current of the battery. Alternatively, the external analog filter 102 may be coupled to terminals of the battery for sensing the output voltage of the battery 124.

The components of the battery sensing device 100 are implemented in the same printed circuit board (PCB) which may be part of a protection circuit module (PCM). When the PCB is part of a PCM, the PCB may be referred to as a PCM board. The external analog filter 102 is not implemented on the same PCB as the battery sensing device 100.

Known integrated solutions use external filtering, as provided by the external analog filter 102 and/or fixed filtering to filter the undesired frequency component on the input signals, as provided by the digital filter 108. This approach has the following limitations:
1. The external analog filter 102, uses external components for the analog filtering which is undesirable in small size PCM boards
2. The selected component values of the external analog filter 102 cannot easily be changed.
3. For the external analog filter 102, using a first order filter that has high attenuation at high frequency will need a cut off frequency in the low frequency range, which can affect the settling time of the signal and corresponding ability to timely detect events triggering protection
4. For the digital filter 108, the predefined digital filtering and down-sampling is decided during the filter design phase and cannot be adjusted to different frequency content.
5. For the digital filter 108, the prior approach prioritizes heavy attenuation of the frequency content, thereby limiting the use and effectiveness of techniques such as impedance spectroscopy for State of Health.

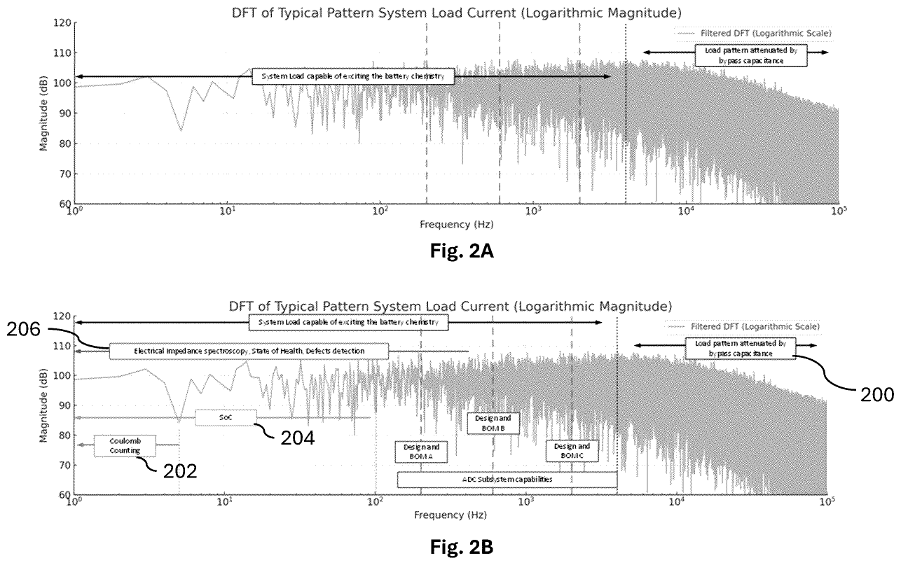

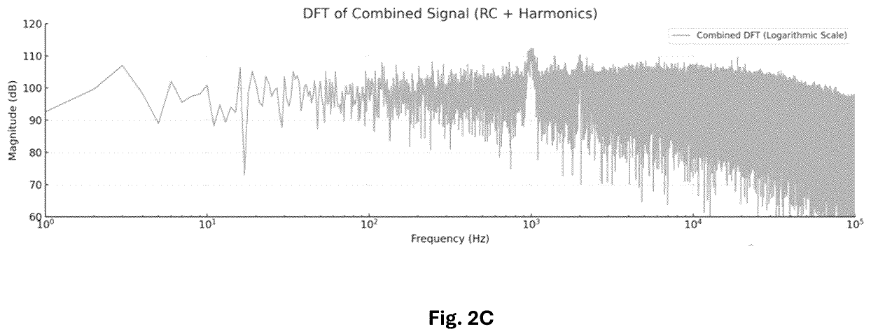

FIG. 2A is a graph of the battery supplied current magnitude versus frequency for a practical implementation of the battery sensing device 100 of FIG. 1.

FIG. 2A illustrates the typical load pattern of a complex mobile system with a simplified decrease in frequency content due to distributed bypass capacitance. The DC component has been excluded. The output current is semi-random due to various subsystem activities. Additionally, the idealized DC current load is constantly perturbed by simultaneous activation of different components, which is driven by the end user's activity.

FIG. 2B shows the graph of FIG. 2A with additional labelling to highlight specific features. Specifically, FIG. 2B shows how different frequency components of the battery supplied current (which may be referred to as the “System Load Current”) may be used to perform fuel gauging and battery diagnostics.

A frequency range 200, corresponding to the higher frequencies are filtered out due to the distributed capacitance, with the remaining frequencies being available for various battery diagnostics and fuel gauging tasks. These tasks include Coulomb counting (using a frequency range 202), determining the state of charge (using a frequency range 204), performing electrical impedance spectroscopy, assessing the state of health or detecting defects and early failures (using a frequency range 206).

Different frequency ranges may be considered for various tasks. If the estimate of the output current or output voltage needed is near DC (i.e. for Coulomb Counting or for open-circuit voltage (OCV) when the system is powered down) most of the frequency component needs to be suppressed while for electrical impedance spectroscopy (EIS), most of the frequency component needs to be preserved.

The capabilities of these tasks are fixed at design time by the ADC 106. This means that the battery sensing device's 100 ability to handle different frequencies is predetermined and cannot be adjusted dynamically, which can limit the effectiveness of certain diagnostic and monitoring functions.

Different levels of current consumption are also acceptable according to the task, and inversely proportional to the frequency and duty cycle at which the estimates are required.

As the capabilities of the battery sensing device 100 is fixed, the current consumption is also constrained because the cutoff frequency and the attenuation (which drives the order of the filter) are predefined.

A short conversion time is possible by either extending cutoff frequency (thus reducing settling time for one-shot/incremental conversions) or reducing the order of the filter. However, in a predetermined architecture such as with the battery sensing device 100, this balance cannot be dynamically adjusted.

The discrete Fourier transform (DFT) spectrum in FIG. 2B is acquired by performing a DFT on a random signal that assumes uniform frequency content. However, it will be appreciated that this a simplification that does not accurately represent a real system. The frequency content is time-variant and will show peaks at certain frequencies. This variation is dependent on the system design, the adopted technology, the revision of the operating system (OS) and software in use, and the end user's usage patterns.

FIG. 2C is a graph showing how the DFT of the battery supplied current signal, as shown in FIG. 2B, changes when a system load is activated at specific frequencies.

FIG. 2C shows the effect of an activity that creates a signal with its harmonics at 1 kHz. As such, a design that employs a fixed scheme for filtering the signal will be conservative and restrictive. Such a system may not be able to address new activity patterns from newly added subsystems or new end user patterns. This limitation can hinder the system's ability to adapt to changing conditions and optimize performance.

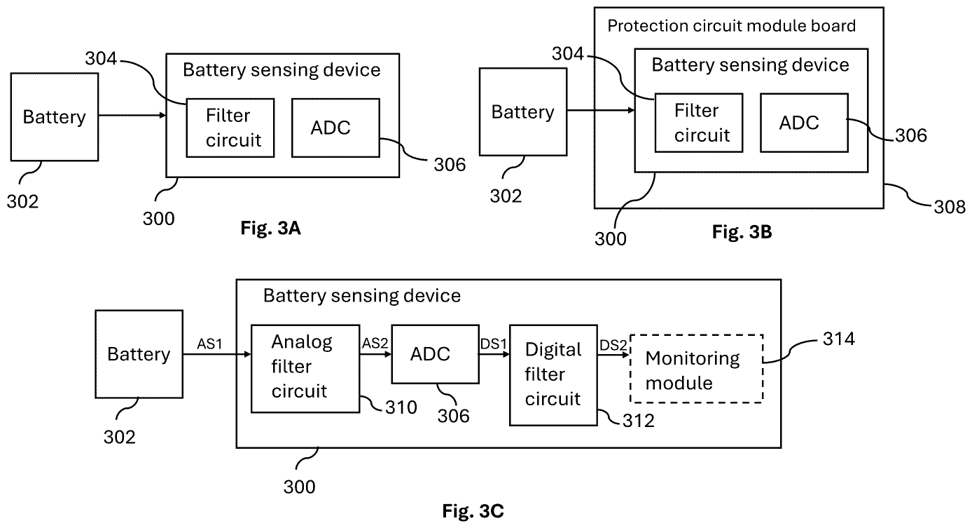

FIG. 3A is a schematic of a battery sensing device 300 for sensing an output voltage and/or an output current of a battery 302 in accordance with a first embodiment of the present disclosure.

The battery sensing device 300 comprises one or more filter circuits 304 and an analog to digital converter (ADC) 306. At least one of the one or more filter circuits 304 and/or the ADC 306 is adjustable. In the present example, a single filter circuit 304 is shown.

“Adjustable” means that one or more aspects relating to the functioning of the component may be altered by adjustment. The adjustment may occur during development. The adjustment may occur after the physical implementation of the battery sensing device 300. The adjustment may occur in real-time and during operation of the battery sensing device 300. The adjustment may be applied by a user or in response to an event in the system implementing the battery 302. An “adjustable” component may, for example, be referred to as “re-programmable”, “re-configurable” or “adaptive”.

The adjustable functionality provided by the battery sensing device 300 contrasts with the operation of the known battery sensing device 100, where the operation of the filters 102, 108, and the ADC 106 cannot be altered after their initial implementation without physically replacing circuit components.

When applied to a filter circuit, “adjustable” means that the functioning of the filter circuit may be changed. For example, the filtering characteristics of the filter circuit may be altered during operation of the battery sensing device 300 as required for specific applications. The filtering characteristics may, for example, comprise the cutoff frequency or the bandwidth.

When applied to an ADC, “adjustable” means that the functioning of the ADC may be changed. For example, the sampling frequency of the ADC may be altered during operation of the battery sensing device 300 as required for specific applications.

FIG. 3B is a schematic of a specific implementation of the battery sensing device 300 of FIG. 3A, in accordance with a second embodiment of the present disclosure. In the present embodiment, the battery sensing device 300 is implemented on a circuit board 308, such as a printed circuit board (PCB) which may be a protection circuit module (PCM) board. The PCM board may, for example, be the PCB of a PCM, with all components of the battery sensing device 300 being implemented on the PCB. This contrasts with the external analog filter 102 of the known battery sensing device 100, which is not implemented on the PCM board.

In a further embodiment, the battery sensing device 300 may be implemented on a chip, which may be referred to as an integrated circuit (IC), with all components of the battery sensing device 300 being implemented on the chip.

In a further embodiment the battery sensing device 300 may be implemented on a chip and a circuit board, with all components of the battery sensing device 300 being implemented across the chip and circuit board.

It will be appreciated that any of the embodiments of the battery sensing device disclosed herein may implemented on a circuit board and/or chip, in accordance with the understanding of the skilled person.

FIG. 3C is a schematic of a specific implementation of the battery sensing device 300 in accordance with a third embodiment of the present disclosure. In the present embodiment, the one or more filter circuits 304 of the battery sensing device 300 comprises an analog filter circuit 310 and a digital filter circuit 312. At least one of the analog filter circuit 310, the digital filter circuit 312 and/or the ADC 306 is configured to be adjustable.

The analog filter circuit 310 is configured to receive a parameter signal AS1 from the battery 302. When the battery sensing device 300 functions as an output current sensor, the parameter signal AS1 may be dependent on the output current of the battery 302. When the battery sensing device 300 functions as an output voltage sensor, the parameter signal AS1 may be dependent on the output voltage of the battery.

The analog filter 310 is further configured to filter the parameter signal AS1 and to provide the parameter signal after filtering (labelled AS2 in FIG. 3C) to the ADC 306.

The ADC 306 is configured to receive the parameter signal AS2 after it has passed through, and been filtered by, the analog filter 310. The ADC 306 then converts the parameter signal AS2, as received, into a digital parameter signal DS1.

The digital filter circuit 312 is configured to receive the digital parameter signal DS1 and to filter the digital parameter signal DS1. The digital parameter signal DS1, after filtering by the digital filter circuit 312, is labelled as DS2 in FIG. 3C.

The battery sensing device 300 may further comprise a monitoring module 314 that is configured to receive the digital parameter signal DS2 and to monitor the battery 302 using the received signal DS2. The monitoring module 314 may be configured to provide, for example a digital signal to estimate state of health, state of charge, or Coulomb counting functionality.

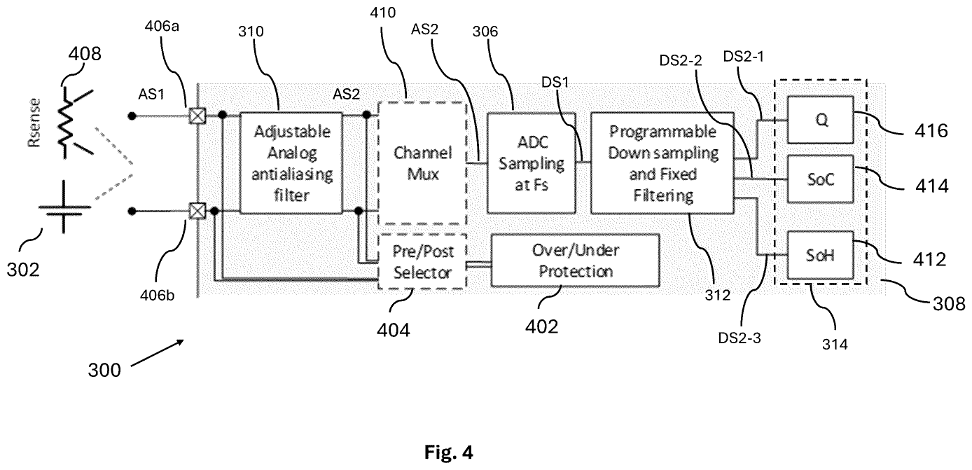

FIG. 4 is a schematic of a specific implementation of the battery sensing device 300 in accordance with a fourth embodiment of the disclosure.

The battery sensing device 300 may comprise an over/under protection circuit 402 that functions to protect the battery 302 when the parameter being sensed is outside of a safe operating zone for the battery 302. For example, for output current sensing, the over/under protection circuit 402 is configured to provide over/under current protection and for output voltage sensing, the over/under protection circuit 402 is configured to provide over/under voltage protection.

The battery sensing device 300 may further comprise a pre/post selector circuit 404 configured to block and/or filter unwanted frequencies.

The pre/post selector circuit 404 is used to select the signal before or after the analog filter 310. The analog filter 310 removes aliasing but in doing so it is also creating a phase delay that can delay the detection of out of range current and voltage. For voltage usually the timing is more relaxed.

In the present example, the battery sensing device 300 comprises input terminals 406a, 406b, such that the input of the battery sensing device 300 is a differential input.

When configured to sense the output current, the input terminals 406a, 406b may be coupled to the terminals of a sense resistor 408. The sense resistor 408 may be in series with the battery 302, such that the voltage across the sense resistor 408, as measured, is dependent on the current provided by the battery 302.

For an implementation where the battery sensing device 300 is used to sense the output voltage, the battery sensing device 300 may further comprise a multiplexer circuit 410. During operation, the multiplexer circuit 410 may function to combine the parameter signal AS2 from the differential inputs into a single output, or select the parameter signal AS2 from one of its two inputs. It will be appreciated that analogue filters potentially need to be duplicated for multiple channels.

The analog filter circuit 310 may comprise an anti-aliasing filter which may, for example, be passive or active. The ADC 306 may have a sampling frequency that is greater than or equal to 20 ksample/s. The anti-aliasing filter may remove or substantially reduce frequencies from the signal to remove or substantially reduce aliasing.

The sampling rate may be provided using the units “KHz” as it is a common unit for sampling rates.

It will be appreciated that the frequency is not restricted to 20 kHz. As an example, the ADC could be an oversampled (Sigma-Delta Converter) possibly clocked at 20 kHz.

The digital filter circuit 312 may be configured to receive the digital parameter signal DS1 and to filter the digital parameter signal DS1. The digital parameter signal DS1 may be filtered to provide three parameter signals DS2-1, DS2-2, DS2-3.

The monitoring module 314 may comprise a state of health unit 412 configured to determine the state of health of the battery 302 based on the received parameter signal DS2-3. The monitoring module 314 may collect the output of the filtering 314 to use for coulomb counting 416, state of charge estimate 414 and State of Health 412.

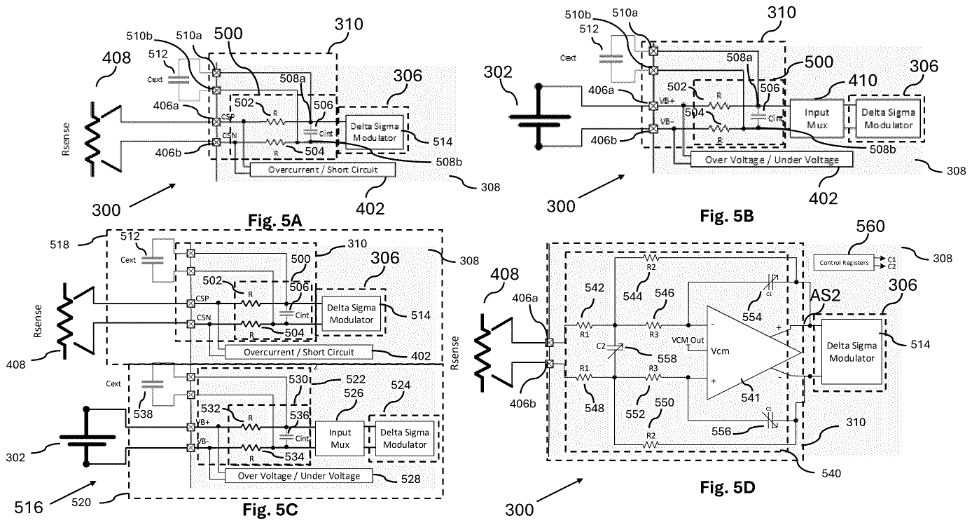

FIG. 5A is a schematic of a portion of a specific implementation of the battery sensing device 300 for sensing the output current of the battery 302, in accordance with a fifth embodiment of the present disclosure. In the present embodiment, there is shown a specific implementation of the analog filter circuit 310 which comprises a passive anti-aliasing filter 500.

The passive anti-aliasing filter 500 comprises resistive elements 502, 504 and a capacitor 506. The resistive element 502 may be coupled to a terminal 508a of the capacitor 506. The resistive element 504 may be coupled to a terminal 508b of the capacitor 506.

One of more of the resistive elements 502, 504 and the capacitor 506 may be variable, with the variability enabling fine-tuning of the frequency characteristics of the analog filter circuit 310.

The battery sensing device 300 may comprise external capacitor terminals 510a, 510b to permit coupling of the capacitor 506 with an external capacitor 512.

The present embodiment shows a possible implementation of a passive integrated anti-aliasing filter 500, where the internal capacitor 506 may be supplemented with the external capacitor 512.

The ADC 306 may comprise a delta sigma modulator 514. The sampling frequency of the ADC 306 may be chosen to be relatively high (for example greater than or equal to 20 ksample/s) and with lower resolution than what is required for the output downstream module such as filtering 312 in FIG. 4.

FIG. 5B is a schematic of a portion of a specific implementation of the battery sensing device 300 for sensing the output voltage of the battery 302, in accordance with a sixth embodiment of the present disclosure. In the present embodiment, there is shown a specific implementation of the analog filter circuit 310 which comprises a passive anti-aliasing filter 500.

Compared with known systems, such as presented in FIG. 1, the passive anti-aliasing filter 500 is moved partially or entirely inside the integrated circuit 308.

Furthermore, the anti-aliasing filter 500 may be sized so that the cutoff frequency is pushed as high into the frequency range as possible. This design allows for more accurate sensing of battery current, for the embodiment presented in FIG. 5A, or battery voltage for the embodiment presented in FIG. 5B, by preserving the frequency content of the input signals up to the highest possible frequency. Moving the anti-aliasing filter onboard allows the following improvements:
Reduced external component count which is highly desirable to minimize the size of PCB for the PCM allowing the battery dimension and therefore capacity to expand accordingly.
Moving the components inside the IC allows for factory calibration on the IC to correct absolute resistor value of the resistors 502, 504 which will magnify the input current of the Delta Sigma Modulator.

FIG. 5C is a schematic of a portion of a battery sensing system 516 comprising a portion of a battery sensing device 518 for sensing the output current of the battery 302 and a portion of a battery sensing device 520 for sensing the output voltage of the battery 302, in accordance with a seventh embodiment of the present disclosure.

The battery sensing device 518 is implemented as described for the battery sensing device 300 of FIG. 5A and the battery sensing device 520 is implemented as described for the battery sensing device 300 of FIG. 5B.

To distinguish between the components of the battery sensing devices 518, 520 different reference numerals are used. The reference numerals of the battery sensing device 518 are consistent with the reference numerals used in FIG. 5A and the reference numerals of the battery sensing device 520 have been updated. Specifically, the battery sensing device 520 comprises an analog filter circuit 522, an ADC 524, a multiplexer circuit 526 and a protection circuit 528. The analog filter circuit 522 comprises a passive anti-aliasing filter 530 comprises resistive elements 532, 534 and a capacitor 536. The capacitor 536 is coupled in parallel with an external capacitor 538. These components function as described for the corresponding components of FIG. 5B, as will be clear to the skilled person.

FIG. 5D is a schematic of a portion of a specific implementation of the battery sensing device 300 for sensing the output current of the battery 302, in accordance with an eighth embodiment of the present disclosure. In the present embodiment, there is shown a specific implementation of the analog filter circuit 310 which comprises an active anti-aliasing filter 540.

The active anti-aliasing filter may, for example, be a first order filter or a second order filter. A first order filter may be less complex than a second order filter. In the present embodiment, the active anti-aliasing filter 540 is a second order filter with configurable bandwidth. The active anti-aliasing filter 540 comprises a differential amplifier 541 configured to provide the filtered parameter signal AS2 as an output, with the signal AS2 being provided as a differential signal in the present example.

The active anti-aliasing filter 540 further comprises resistors 542, 544, 546, 548, 550, 552 and variable capacitors 554, 556, 558. The variable capacitors 554, 556, 558 enable adjustment of the analog filter circuit 310. The adjustment may be applied by a controller 560.

The active anti-aliasing filter 540 enables pre-amplification of the input signals received at the input terminals 406a, 406b which can ease the design burden of the downstream ADC 306.

In a further embodiment, the battery sensing device 300 may switch to an instrumentation amplifier when a high input impedance is required.

Both passive and active implementations of the anti-aliasing filter enable adjustment of the anti-aliasing cut off frequency.

By adding the ability to adjust at run time the analog anti-aliasing filter 310, the system now has the ability to preserve more of the frequency content of the original signal or to increase the filtering to suppress signal that could create aliasing.

Since this configuration may be applied by a register (for example by controlling switches that are increasing or decreasing the filtering capacitor associated in active anti-aliasing filter) it is now possible to use the same IC, the same PCB, the same BOM and change it in software during development and also in real time if the need arises due to unforeseen use cases or new configurations that change activity patterns of any of the subsystem downstream.

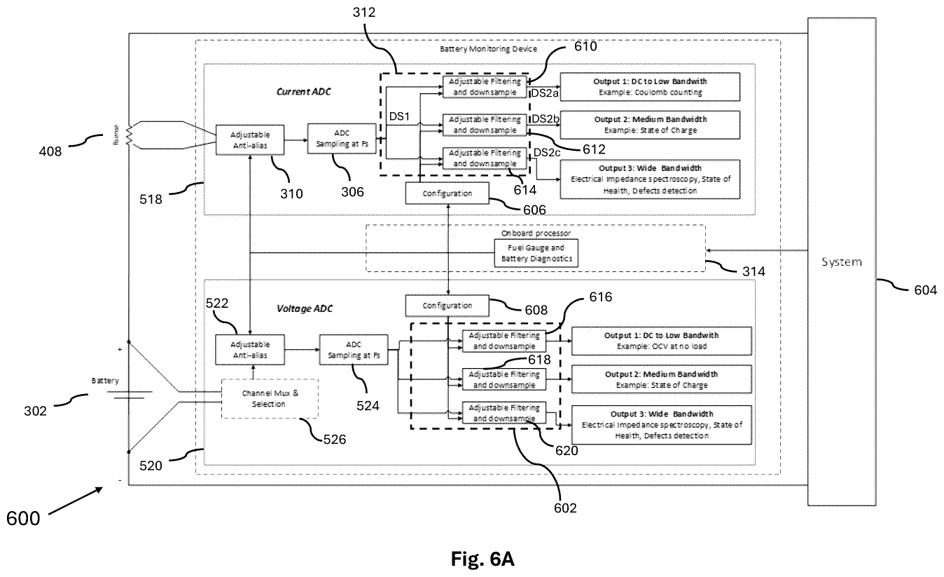

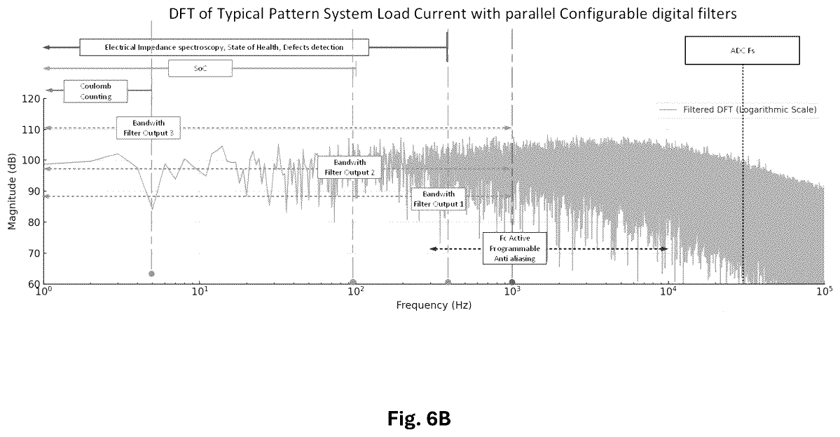

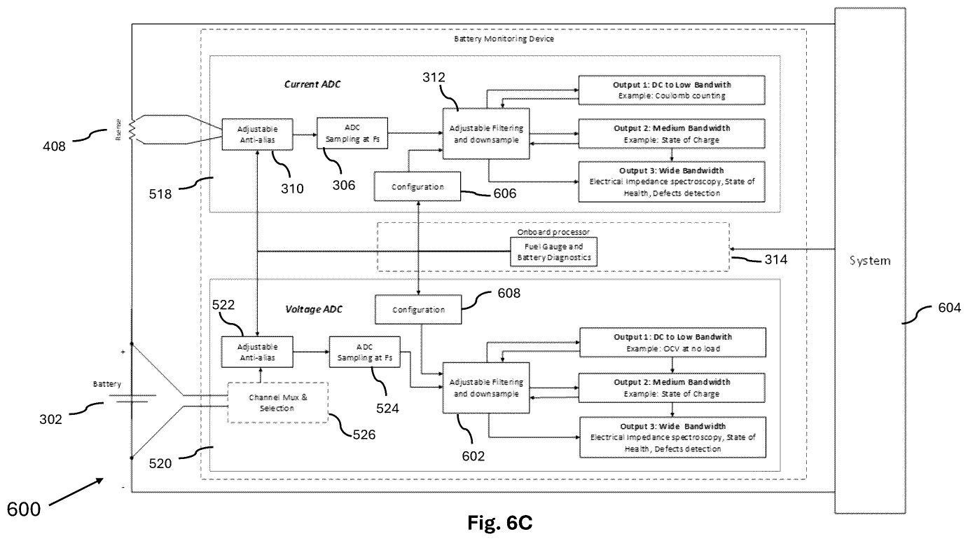

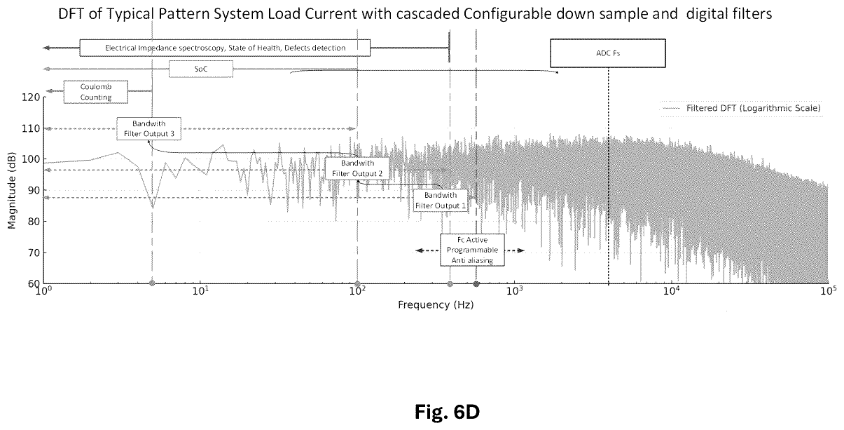

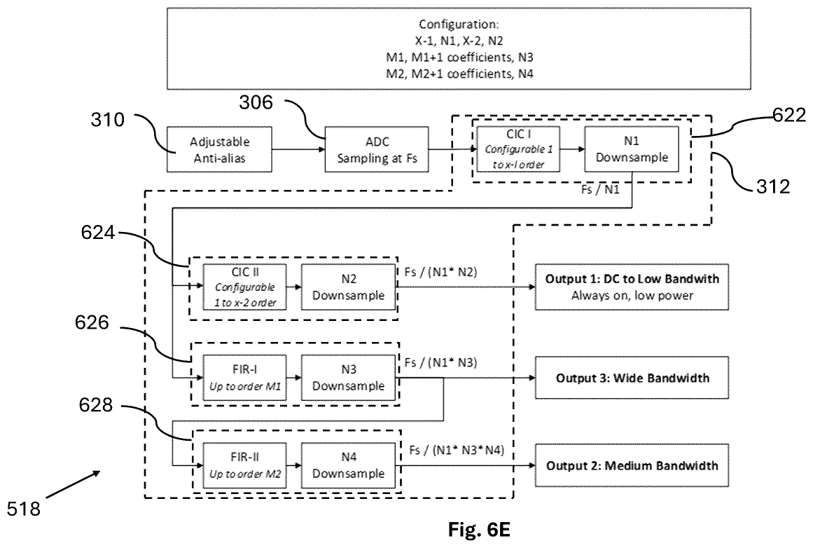

FIG. 6A is a schematic of a battery sensing system 600 comprising specific implementations of the battery sensing devices 518, 520, in accordance with a ninth embodiment of the present disclosure. The battery sensing device 520 comprises a digital filter circuit 602 which corresponds to the digital filter circuit 312, and functions substantially as described for the digital filter circuit 312, in accordance with the understanding of the skilled person.

In the present example, the battery 302 is used to power a system 604. Additionally, the monitoring module 314 is shared between both battery sensing devices 518, 520. During operation, the monitoring module 314 may adjust the analog filter circuits 310, 522, the digital filter circuit 312 via a configuration block 606 or the digital filter circuit 602 via a configuration block 608.

In further embodiments, the monitoring module 314, and/or the system 604 using the battery 302, may be configured to adjust at least one of the analog filter circuit 310, the analog filter circuit 522, the digital filter circuit 312, the digital filter circuit 602, the ADC 306 and/or the ADC 524. The monitoring module 314 may be referred to as a “fuel gauge”.

Such adjustments could be implemented based on one or more of the following:
Detecting specific software execution on the system (i.e. GPU intensive task).
Detecting certain system usage patterns.
Monitoring the amount of noise of Z(f)=I(f)/V(f), where Z(f) is impedance as a function of frequency, I(f) is the output current of the battery 302 as a function of frequency, and V(f) is the output voltage of the battery 302 as a function of frequency.
Detecting high frequency signals that need more attenuation (for example by adding a filter for the detection of the signals, for example by adding another step in the cascade or another parallel filter).
Receiving or detecting the need to lower the current consumption, thus needing faster conversion with faster settling time with the interval between conversion either unchanged or extended, thus requiring less power.

This allows a user to dynamically select the best compromise for bandwidth, resolution and current consumption.

In summary, the adjustment may be carried out in real-time and may be based on one or more of; software execution on the system 604, detection of usage patterns of the system 604, noise, detection of high frequency signals and/or detection of a requirement for reduced current consumption.

The digital filter circuit 306 comprises a plurality of digital filters 610, 612, 614 arranged in a parallel configuration. The parameter signal DS1 is provided to each of the digital filters 610, 612, 614 which each filter the digital parameter signal DS1 using a different filter profile. The digital filters 610, 612, 614 each output filtered digital parameters signals DS2a, DS2b, DS2c suitable for different applications. For example, the digital filter 610 filters from DC to a low bandwidth, such that the digital parameter signal DS2a is suitable for coulomb counting; the digital filter 612 filters at a medium bandwidth such that the digital parameter signal DS2b is suitable for a state of a charge assessment; and the digital filter 614 filters to a wide bandwidth such that the digital parameter signal DS2c is suitable for a state of health assessment.

Each of the digital filters 610, 612, 614 may be configured to downsample the parameter signal DS1.

The digital filter circuit 602 comprises a plurality of digital filters 616, 618, 620 arranged in a parallel configuration. Each of the digital filters 616, 618 and 620 may function substantially as described for the digital filters 610, 612 and 614, respectively, in accordance with the understanding of the skilled person.

One or more of the digital filters 610-620 may, for example, be a infinite impulse response (IIR) filter, a finite impulse response filter (FIR) or a cascaded integrator comb (CIC) filter.

FIG. 6B is a graph of the battery output current magnitude versus frequency for a practical implementation of the battery sensing device 518 of FIG. 6A.

In summary, the battery sensing system 600 of FIG. 6A is an embodiment of the disclosure with an ADC subsystem (provided by the ADCs 306, 524) with highly integrated and digitally configurable parallel filtering capabilities (provided by the digital filter circuits 312, 602).

The present embodiment provides adjustable filtering and down sampling capabilities. By being able to adjust the down sampling and filtering characteristic the different tasks required for Fuel Gauging can be served with the correct frequency content, as shown by the outputs of the digital filters 610-620 in FIG. 6A and as illustrated on the graph shown in FIG. 6B.

FIG. 6C is a schematic of a battery sensing system 600 comprising specific implementations of the battery sensing devices 518, 520, in accordance with a tenth embodiment of the disclosure. In the present embodiment, the digital filters of each of the digital filter circuits 312, 602 are in a cascaded configuration.

FIG. 6D is a graph of the output current magnitude versus frequency for a practical implementation of the battery sensing device 518 of FIG. 6C.

In summary, the battery sensing system 600 of FIG. 6C is an embodiment of the disclosure with an ADC subsystem (provided by the ADCs 306, 524) with highly integrated and digitally configurable cascaded filtering capabilities (provided by the digital filter circuits 312, 602).

The present embodiment further improves the architecture by cascading the configurable digital filters and reducing power consumption due to the progressively lower data rate and reduced logic count by accepting a small reduction in configuration flexibility.

FIG. 6E is a schematic of a specific implementation of the battery sensing device 518 with a specific implementation of the digital filter circuit 312 of FIG. 6C. It will be appreciated that this specific arrangement may also be used for the digital filter circuit 602 of FIG. 6C. The digital filter circuit 312 comprises digital filters 622, 624, 626, 628.

The architecture with internal anti-aliasing and cascaded digital filters can be further enhanced for current consumption by using a hybrid cascaded-parallel approach that depends on which signal chains are enabled all the time, and which ones are turned on with a low duty cycle (which could be for 1 to N samples at each low duty cycle acquisition) as provided by the specific implementation shown in FIG. 6E.

In specific embodiments, the following constraints may be added where appropriate in the implementation to reduce the amount of computation, thereby allowing for a more power efficient implementation and reducing complexity and area:
Using a downsample rate matching the order of the filter (M1=N3, M2=N4)
Sharing and re-using the same computation resources by filters running at different rates by running the arithmetical cores at a higher rate to be able to time-multiplex
Constrain to use of a symmetrical FIR filter for N order filter so that instead of M only M/2 or M/2+1 number of coefficients needs to be stored.

The variables may be defined as follows:
M1: Filter order of FIR-I,
M2: Filter order of FIR-II,
N1: Downsampling ratio of N1 Downsample,
N2: Downsampling ratio of N2 Downsample,
N3: Downsampling ratio of N3 Downsample,
N4: Downsampling ratio of N4 Downsample

In terms of constraints, some upper bounds for the CIC order, FIR order, coefficients resolution, math precision and down sample range may be defined.

In summary, battery sensing devices of present disclosure provide an adaptive system for sensing the output voltage and/or output current of a battery. Specific embodiments of the battery sensing devices may comprise:
A high sampling frequency ADC 20 ksample/s or above. It will be appreciated that the frequency is not restricted to 20 kHz.
An onboard integrated/part-integrated anti-aliasing filter with adjustable frequency that is sized to push the cutoff frequency as high as possible. The cut-off frequency may be adjusted to the desired signal bandwidth.
An integrated differential amplifier with an active programmable anti-aliasing filter.
Configurable digital filters that can be adjusted dynamically.
The ability to change the anti-aliasing cutoff frequency both in passive and active.

Embodiments of the present disclosure can allow for accurate battery current and voltage sensing over a wide range of operating conditions by:
Preserving the frequency content of the input signals up to the highest possible frequency and sharply attenuating frequencies beyond that to avoid distortion due to aliasing.
Reducing the number of external components required, which is highly desirable for minimizing the size of the PCB for a battery PCM.
Allowing factory calibration on the IC to remove offset introduced by the mismatch of resistors.
Enabling real-time adjustment of the analog and digital filtering by either the system directly or the fuel gauge.
Dynamically adjusting the filter to balance attenuation of suppressed frequency content, effective resolution, bandwidth of the converted signal, and current consumption

Embodiments of the present disclosure improve on known methods by improving on the accuracy of battery sensing and allowing for better fuel gauging and battery health management.

Embodiments of the present disclosure provide integrated re-programmable analog and digital filters for sensing the output voltage and output current of a battery. The filters may be pre-adjusted or operated in an on-the-fly mode. For example, the digital filters may be adjusted based on the load frequency. As compared to the fixed filters of the known systems, such as presented in FIG. 1, embodiments of the present disclosure allows for accurate battery current and voltage sensing over a wide range of operating conditions.

In summary, embodiments of the present disclosure may be used to:
1. Acquire voltage and current information from a battery, whilst preserving the frequency content of the input signals up to the highest frequency possible (e.g. 100 Hz) and sharply attenuating after that to avoid any distortion due to aliasing.
2. Achieve filtering whilst minimizing the number of external components required.
3. Dynamically adjust the filter to balance attenuation of suppressed frequency content, effective resolution, bandwidth of the converted signal and current consumption.

It will be appreciated that specific embodiment of the present disclosure may use adaptive filtering with changes to the filters in real-time.

Common reference numerals and variable between figures represent common features.

Various improvements and modifications may be made to the above without departing from the scope of the disclosure.

1. A battery sensing device for sensing an output voltage and/or an output current of a battery, the battery sensing device comprising:
one or more filter circuits; and
an analog to digital converter (ADC); wherein:
at least one of the one or more filter circuits and/or the ADC is adjustable.

2. The battery sensing device of claim 1, wherein the one or more filter circuits comprises:
an analog filter circuit; and
a digital filter circuit;
wherein at least one of the analog filter circuit, the digital filter circuit and/or the ADC is adjustable.

3. The battery sensing device of claim 2, wherein:
the analog filter circuit is configured to:
receive a parameter signal from the battery, the parameter signal being dependent on the output voltage or the output current; and
filter the parameter signal;
the ADC is configured to:
receive the parameter signal after filtering by the analog filter circuit; and
convert the parameter signal, as received by the ADC, to a digital parameter signal; and
the digital filter circuit is configured to:
receive the digital parameter signal; and
filter the digital parameter signal.

4. The battery sensing device of claim 3, wherein:
the parameter signal is dependent on the output voltage; and
the battery sensing device comprises a multiplexer circuit, the parameter signal being provided to the ADC, after filtering by the analog filter circuit, via the multiplexer circuit.

5. The battery sensing device of claim 3, further comprising an over/under protection circuit.

6. The battery sensing device of claim 3, further comprising:
a first input terminal and a second input terminal configured to be couplable to:
battery terminals of the battery for sensing the parameter signal when the parameter signal is dependent on the output voltage; or
sense resistor terminals of a sense resistor coupled to the battery for sensing the parameter signal when the parameter signal is dependent on the output current.

7. The battery sensing device of claim 6, wherein the analog filter circuit comprises a passive anti-aliasing filter or an active anti-aliasing filter.

8. The battery sensing device of claim 7, wherein the passive anti-aliasing filter comprises:
a first capacitor;
a first resistive element coupled to a first terminal of the first capacitor; and
a second resistive element coupled to a second terminal of the first capacitor.

9. The battery sensing device of claim 8, further comprising external capacitor terminals configured to permit parallel coupling of the first capacitor with a first external capacitor.

10. The battery sensing device of claim 7, wherein the active anti-aliasing filter comprises a differential amplifier configured to provide the filtered parameter signal to the ADC.

11. The battery sensing device of claim 10, wherein the active anti-aliasing filter comprises a plurality of variable capacitors configured to enable adjustment of the analog filter circuit.

12. The battery sensing device of claim 3, wherein the digital filter circuit comprises a plurality of digital filters arranged in a parallel configuration or arranged in a cascaded configuration.

13. The battery sensing device of claim 12, wherein each of the plurality of digital filters is configured to downsample the parameter signal.

14. The battery sensing device of claim 3, further comprising a monitoring module configured to:
receive the digital parameter signal after filtering; and
monitor the battery using the digital parameter signal, as received.

15. The battery sensing device of claim 14, wherein the monitoring module or a system using the battery is configured to adjust the at least one of the analog filter circuit, the digital filter circuit and/or the ADC.

16. The battery sensing device of claim 15, wherein the monitoring module or the system using the battery is configured to adjust the at least one of the analog filter circuit, the digital filter circuit and/or the ADC based on one or more of:
software execution on the system;
detection of usage patterns;
noise;
detection of high frequency signals; and/or
detecting a requirement for reduced current consumption.

17. The battery sensing device of claim 14, wherein the monitoring module comprises:
an output tailored for state of health; and/or
an output tailored for state of charge; and/or
an output tailored for Coulomb Counting.

18. The battery sensing device of claim 1 implemented on a circuit board or a chip.

19. A battery sensing system comprising:
a first battery sensing device for sensing an output voltage of a battery, the battery sensing device comprising:
one or more first filter circuits; and
a first analog to digital converter (ADC); and
a second battery sensing device for sensing an output current of the battery, the battery sensing device comprising:
one or more second filter circuits; and
a second ADC;
wherein at least one of the one or more first filter circuits and/or the first ADC and/or the one or more second filter circuits and/or the second ADC is adjustable.

20. A method of providing a battery sensing device for sensing an output voltage and/or an output current of a battery, the method comprising:
providing one or more filter circuits; and
providing an analog to digital converter (ADC);
wherein at least one of the one or more filter circuits and/or the ADC is adjustable.
